(19) United States
(12) Patent Application Publication
(10) Pub. No.: US 2026/0261247 A1
(43) Pub. Date: Sep. 3, 2026

(54) SEMICONDUCTOR DEVICE AND METHOD THEREOF

(71) Applicant: RENESAS ELECTRONICS CORPORATION, Tokyo (JP)

(72) Inventors: Hisayasu SATO, Tokyo (JP); Tomoumi YAGASAKI, Tokyo (JP)

(21) Appl. No.: 19/541,533

(22) Filed: Feb. 17, 2026

(30) Foreign Application Priority Data
Feb. 28, 2025 (JP) 2025-031042

(51) Int. Cl. H03F 3/68; H03F 1/02; H03F 1/22; H03F 3/21; H03F 3/60

(52) U.S. Cl. CPC H03F 3/68; H03F 1/0205; H03F 1/0277; H03F 1/223; H03F 3/211; H03F 3/602

(57) ABSTRACT

A semiconductor device includes a plurality of amplifiers configured to amplify an input phase‑modulated signal and to generate an output signal by summing respective output voltages, and an amplitude control circuit configured to output a selection signal for switching, among the plurality of amplifiers, a number of amplifiers that are simultaneously controlled to an operating state. A number of stages of change in the number of amplifiers simultaneously controlled to the operating state is defined as a switching stage number. The plurality of amplifiers include at least one first amplifier configured to change a voltage level of the output signal by an amount smaller than a unit amplitude obtained by dividing a maximum amplitude of the output signal by the switching stage number, and at least one second amplifier configured to change the voltage level of the output signal by an amount larger than the unit amplitude.

### CROSS-REFERENCE TO RELATED APPLICATIONS

The disclosure of Japanese Patent Application No. 2025-031042 filed on February 28, 2025, including the specification, drawings and abstract is incorporated herein by reference in its entirety.

### BACKGROUND

The present disclosure relates to a semiconductor device and its method, particularly to a semiconductor device having multiple amplifiers and its control method.

The semiconductor device used in wireless communication is equipped with a power amplifier that drives the antenna. Recently, many techniques have been proposed to discretely change the signal level of the output signal by digitally controlling the signal level of the power amplifier's output signal. Such technology related to power amplifiers is disclosed in Non Patent Document 1.

[Non Patent Document 1] Minyoung Song, et al. "A Low Power 6-9GHz IEEE 802.15.4a/4z Compliant IR-UWB Transceiver With Pulse Pre-Emphasis Achieving High ToA Precision," IEEE Solid State Circuits Letters, November 2023, p.297-300.

The power amplifier discloses a Non Patent Document 1 performs amplitude control of the output signal with 4-bit precision (16 levels). Furthermore, the power amplifier discloses a Non Patent Document 1 pseudo-generates a pulse waveform by dividing the maximum amplitude of the desired pulse waveform into 16 equal parts and setting the time of the intersection of the waveform and the 16 equal division lines as a delay for each stage.

### SUMMARY

However, in Non Patent Document 1, it is necessary to increase the number of digital control bits and improve resolution to address the increase in sidelobes and noise. Therefore, in Non Patent Document 1, to achieve a reduction in sidelobes and noise, it is necessary to increase the number of power amplifier units, enlarge the circuit scale of the control circuit to increase the number of digital control bits, and increase the signal lines, leading to problems such as increased chip area, complicated signal line layout, and increased power consumption.

Other objects and novel features will become apparent from the description of this specification and the accompanying drawings.

A semiconductor device according to one embodiment amplifies an input phase-modulated signal and generates an output signal by adding and synthesizing each output voltage with multiple amplifiers. It includes an amplitude control circuit that outputs a selection signal to sequentially switch the number of amplifiers controlled to be in an operational state based on a predetermined sequence, at non-uniform time intervals and in multiple stages. The number of change stages of the amplifiers controlled to be in an operational state simultaneously is referred to as the switching stage number. The multiple amplifiers include at least one first amplifier that changes the voltage level of the output signal by a smaller amount than the unit amplitude obtained by dividing the maximum amplitude of the output signal by the switching stage number, and at least one second amplifier that changes the voltage level of the output signal by a larger amount than the unit amplitude.

According to a semiconductor device of one embodiment, it is possible to reduce the noise level of sidelobes without increasing the number of digital control bits.

### BRIEF DESCRIPTION OF THE DRAWINGS

FIG. 1 is a block diagram of a semiconductor device according to the first embodiment.

FIG. 2 is an example of an amplitude control table applied to the semiconductor device according to the first embodiment.

FIG. 3 is a timing chart explaining the operation of the semiconductor device according to the first embodiment.

FIG. 4 is a graph explaining the frequency spectrum characteristics of the output signal of the semiconductor device according to the first embodiment.

FIG. 5 is a block diagram of a semiconductor device according to the second embodiment.

FIG. 6 is a first example of an amplitude control table applied to the semiconductor device according to the second embodiment.

FIG. 7 is a second example of an amplitude control table applied to the semiconductor device according to the second embodiment.

FIG. 8 is a block diagram of an amplifier according to the third embodiment.

FIG. 9 is a block diagram of a semiconductor device according to the fourth embodiment.

### DETAILED DESCRIPTION

### First Embodiment

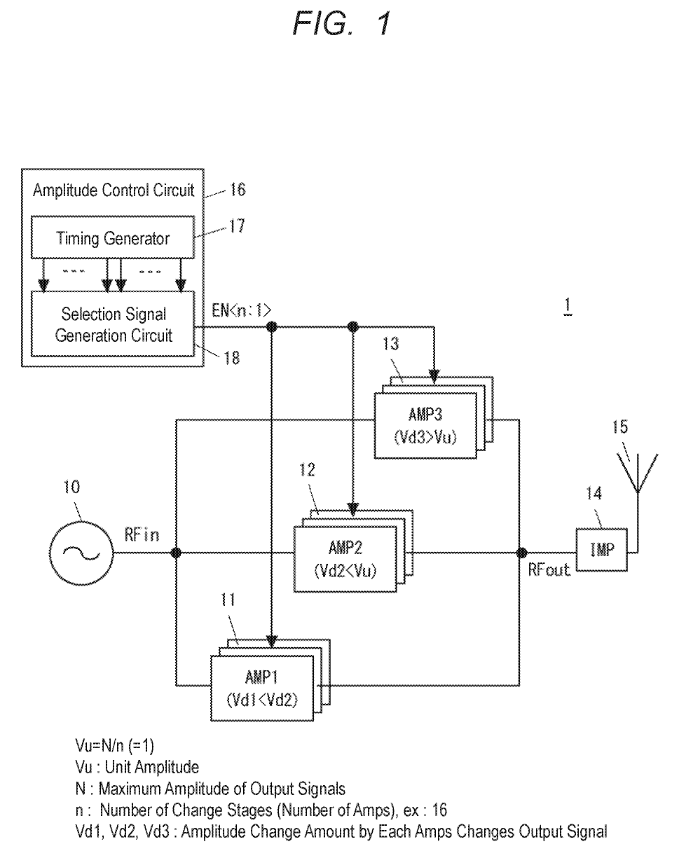

A preferred embodiment of the present invention will be described with reference to the accompanying drawings. First, FIG. 1 shows a block diagram of a semiconductor device 1 according to the first embodiment. As shown in FIG. 1, the semiconductor device 1 according to the first embodiment includes a phase modulation signal generator 10, amplifier units 11, 12, 13, an impedance matching circuit 14, an antenna 15, and an amplitude control circuit 16. In the semiconductor device 1, it is sufficient if the amplifier units 11, 12, 13 are at least formed on the semiconductor substrate. In semiconductor device 1, the impedance matching circuit 14 and the antenna 15 may be provided separately as individual components from the semiconductor device 1. In other words, which processing block is formed on the semiconductor substrate is determined by product specifications and is not particularly limited.

The phase modulation signal generator 10 generates a phase modulation signal and provides it as an input signal RFin to the amplifier units 11, 12, 13. In the semiconductor device 1 according to the first embodiment, the input signal RFin is amplified using multiple amplifiers and the amplitude control circuit 16 and output as the output signal RFout. In the semiconductor device 1, the output voltages of multiple amplifiers are added and synthesized to output the output signal RFout. In the semiconductor device 1, based on a sequence determined by the amplitude control circuit 16, the number of amplifiers controlled to be in an operational state simultaneously is sequentially switched at non-uniform time intervals and in multiple stages, and a selection signal is output.

In semiconductor device 1, by changing the number of amplifiers in the operational state over time, the amplitude of the output signal RFout is modulated. Here, in the following description, the number of change stages of amplifiers controlled to be in an operational state simultaneously by the amplitude control circuit 16 is referred to as the switching stage number. Then, the semiconductor device 1 transmits the output signal RFout to the antenna 15 via the impedance matching circuit 14.

Here, the configuration of multiple amplifiers in semiconductor device 1 will be described in detail. In the semiconductor device 1 according to the first embodiment, as multiple amplifiers, it includes at least one first amplifier and at least one second amplifier. The first amplifier changes the voltage level of the output signal RFout by a smaller amount than the unit amplitude Vu obtained by dividing the maximum amplitude of the output signal RFout by the switching stage number. The second amplifier changes the voltage level of the output signal RFout by a larger amount than the unit amplitude.

In the example shown in FIG. 1, amplifier units 11, 12 are shown as the first amplifier. Here, in the semiconductor device 1 according to the first embodiment, as the first amplifier, it includes a first small amplitude amplifier (e.g., amplifier unit 11) and a second small amplitude amplifier (e.g., amplifier unit 12). The amplifier unit 11 changes the signal level of the output signal by an amplitude change amount smaller than the unit amplitude Vu. The amplifier unit 12 changes the amplitude of the output signal by a larger change amount than the first small amplitude amplifier and a smaller change amount than the unit amplitude. Also, amplifier unit 13 is shown as the second amplifier.

Here, the maximum amplitude, unit amplitude, amplitude change amount, and change stage number of the output signal RFout in this specification will be explained. In this specification, the maximum amplitude of the output signal RFout is denoted as N. Then, the value obtained by dividing the maximum amplitude N by the change stage number n of the output signal RFout is defined as the unit amplitude Vu. And, for example, the unit amplitude Vu is set to "1". Also, the change stage number is the same as the number of amplifiers (number of amps) included in the amplifier units 11, 12, 13 in the semiconductor device 1 shown in FIG. 1, and for example, 16 are assumed. Furthermore, the amplitude change amount by which one amplifier included in the amplifier unit 11 changes the output signal RFout is denoted as Vd1. The amplitude change amount by which one amplifier included in the amplifier unit 12 changes the output signal RFout is denoted as Vd2. The amplitude change amount by which one amplifier included in the amplifier unit 13 changes the output signal RFout is denoted as Vd3.

In the following description, in the first embodiment, an example is explained where the amplitude change amount Vd1 of the amplifier included in the amplifier unit 11 is set to 4/9, the amplitude change amount Vd2 of the amplifier included in the amplifier unit 12 is set to 8/9, and the amplitude change amount Vd3 of the amplifier included in the amplifier unit 13 is set to 12/9, relative to the unit amplitude Vu. Note that when the amplitude change amount of each amplifier is set in this way, the sum of the voltage change amounts of multiple amplifiers becomes the same value as the maximum amplitude N.

Also, as shown in FIG. 1, in the semiconductor device 1 according to the first embodiment, the amplitude control circuit 16 includes a timing generator 17 and a selection signal generation circuit 18. The timing generator 17 instructs the selection signal generation circuit 18 on the timing to raise the selection signal EN and the timing to lower the selection signal EN based on a preset sequence. The timing for raising and lowering the selection signal EN provided by the timing generator 17 is non-uniform in the semiconductor device 1. The selection signal generation circuit 18 switches the logic level of the selection signal EN based on instructions from the timing generator 17. In the semiconductor device 1 according to the first embodiment, since the total number of amplifiers included in the amplifier units 11, 12, 13 is 16, the selection signal generation circuit 18 outputs selection signals EN<1> to EN<16>. That is, in the example shown in FIG. 1, n is set to 16.

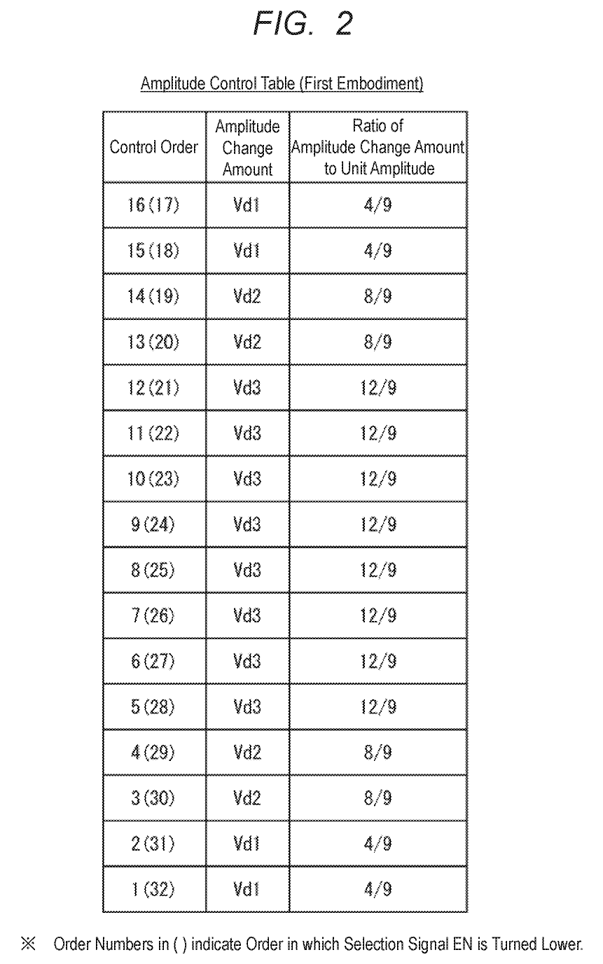

Here, the control sequence of the amplitude control circuit 16 will be explained. FIG. 2 shows an example of an amplitude control table applied to the semiconductor device according to the first embodiment. The example shown in FIG. 2 assumes the generation of an output signal RFout in the shape of one cycle of a waveform derived from the Blackman window function.

In the semiconductor device 1 according to the first embodiment, waveform shaping is performed by the first amplifier with a small amplitude change width at the start and end points of the waveform where the curvature of the Blackman window function waveform becomes large, and near the upper vertex of the Blackman window function waveform. Also, in the semiconductor device 1 according to the first embodiment, waveform shaping is performed by the second amplifier with a large amplitude change width in the portion where the curvature is small and linearity is high. Furthermore, the amplitude control circuit 16 of the semiconductor device 1 defines a sequence from the first to the thirty-second control order and switches the amplifier from standby state to operating state, or from operating state to standby state according to this sequence. In other words, in the first embodiment, the sequence of the amplitude control circuit 16 is defined such that the waveform of the portion with large curvature of the output signal is shaped by the output voltage of the first amplifier, and the waveform of the portion with small curvature of the output signal is shaped by the output voltage of the second amplifier.

In the example shown in FIG. 2, in the first two control steps, the amplifiers included in the amplifier unit 11, which have an amplitude change amount of 4/9, are sequentially switched to the operating state. In the next third and fourth control steps, the amplifiers included in the amplifier unit 12, which have an amplitude change amount of 8/9, are sequentially switched to the operating state. Next, in the fifth to twelfth control steps, the amplifiers included in the amplifier unit 13, which have an amplitude change amount of 12/9, are sequentially switched to the operating state. In the next thirteenth and fourteenth control steps, the amplifiers included in the amplifier unit 12, which have an amplitude change amount of 8/9, are sequentially switched to the operating state. In the next fifteenth and sixteenth control steps, the amplifiers included in the amplifier unit 11, which have an amplitude change amount of 4/9, are sequentially switched to the operating state. Through these first to sixteenth control steps, the waveform is ramped up from the lowest voltage to the highest voltage.

Subsequently, in the seventeenth and eighteenth control steps, the amplifiers included in the amplifier unit 11, which have an amplitude change amount of 4/9, are sequentially switched to the standby state. In the next nineteenth and twentieth control steps, the amplifiers included in the amplifier unit 12, which have an amplitude change amount of 8/9, are sequentially switched to the standby state. Next, in the twenty-first to twenty-eighth control steps, the amplifiers included in the amplifier unit 13, which have an amplitude change amount of 12/9, are sequentially switched to the standby state. In the next twenty-ninth and thirtieth control steps, the amplifiers included in the amplifier unit 12, which have an amplitude change amount of 8/9, are sequentially switched to the standby state. In the next thirty-first and thirty-second control steps, the amplifiers included in the amplifier unit 11, which have an amplitude change amount of 4/9, are sequentially switched to the standby state. Through these seventeenth to thirty-second control steps, the waveform is ramped down from the highest voltage to the lowest voltage.

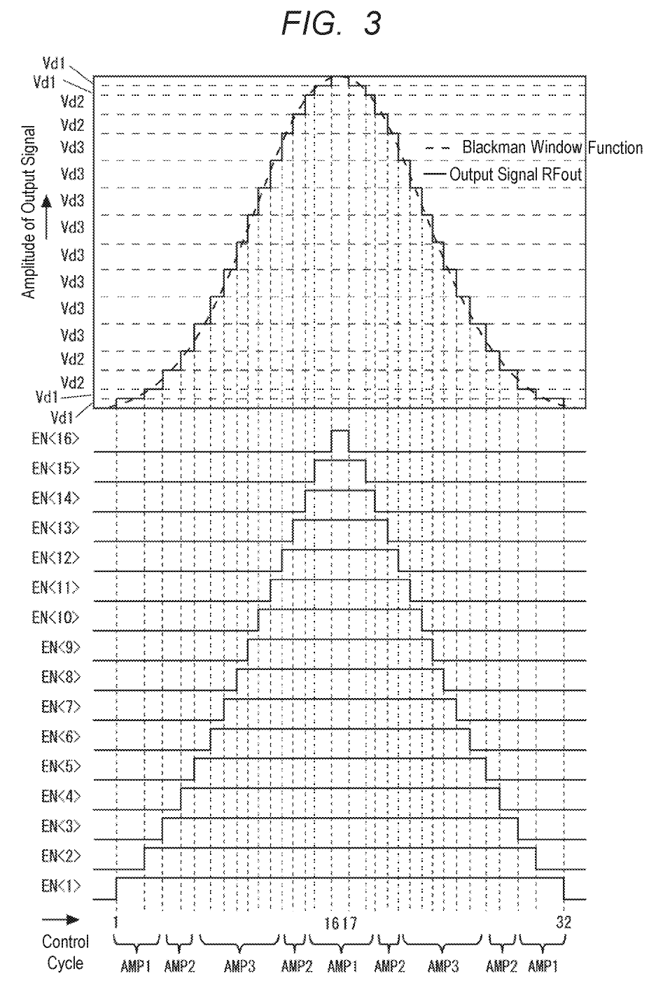

The waveform shaped by the control shown in FIG. 2 will be described. FIG. 3 shows a timing chart explaining the operation of the semiconductor device according to the first embodiment. In FIG. 3, the upper part shows a waveform graph with the horizontal axis as time and the vertical axis as the amplitude of the output signal RFout, and the lower part shows the signal level transition waveform of the selection signal EN with the horizontal axis as time.

As shown in FIG. 3, in the semiconductor device 1 according to the first embodiment, the output signal RFout is generated to reproduce the waveform derived by the Blackman window function in discrete values. At this time, the timing at which each amplifier transitions from standby state to operating state (for example, the timing when the selection signal EN switches from low level to high level) is set so that the waveform of the Blackman window function intersects near the midpoint of the voltage maintenance period (the period during which the voltage of the output signal RFout remains constant) after the voltage level of the output signal RFout changes. In such a setting, the timing at which the amplitude control circuit 16 switches the logic level of the selection signal EN becomes non-uniform.

Also, as shown in FIG. 3, in the semiconductor device 1 according to the first embodiment, amplifiers with smaller amplitude change amounts are used in portions where the curvature of the Blackman window function waveform becomes larger. By doing so, in the semiconductor device 1 according to the first embodiment, it becomes possible to reduce the quantization error of the output signal RFout with respect to the waveform of the Blackman window function without increasing the number of control bits from 4 bits.

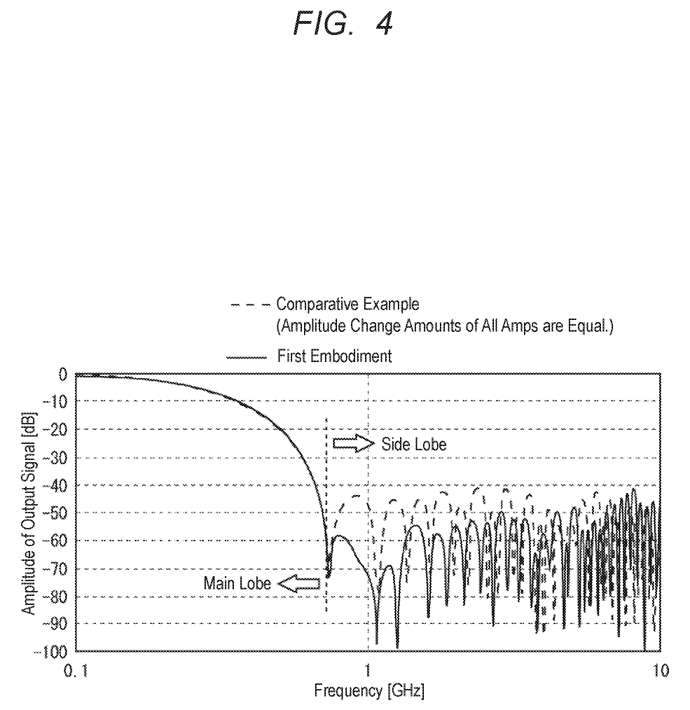

Next, FIG. 4 shows a graph explaining the frequency spectrum characteristics of the output signal of the semiconductor device 1 according to the first embodiment. In FIG. 4, as a comparative example, the frequency spectrum characteristics when all amplifiers are operated with an amplitude change amount that divides the maximum amplitude of the output signal RFout into 16 equal parts to generate the waveform of the Blackman window function are shown as a comparative example.

As shown in FIG. 4, the semiconductor device 1 according to the first embodiment has frequency spectrum characteristics of the main lobe that are almost the same as the comparative example, but there are differences in the frequency spectrum characteristics of the side lobes in the region with frequencies higher than the main lobe. The signal in the frequency band of this side lobe becomes quantization noise (hereinafter simply referred to as noise). Specifically, in the frequency band close to the main lobe among the side lobes, the semiconductor device 1 according to the first embodiment has lower frequency spectrum characteristics than the comparative example. The noise in this frequency band is close in frequency to the main lobe and is difficult to remove with a low-pass filter or the like. On the other hand, noise in the frequency band far from the main lobe is easy to remove with a low-pass filter or the like.

From the above description, semiconductor device 1 according to the first embodiment can perform high-precision waveform generation with reduced quantization noise by using multiple amplifiers with different amplitude change amounts, without increasing the number of control bits. This makes it possible to reduce the noise of the side lobes close to the main lobe frequency band of the output signal RFout. By reducing the noise of the side lobes close to the main lobe frequency band of the output signal RFout, it becomes possible to suppress unwanted radiation and achieve good EMC characteristics.

Also, in semiconductor device 1 according to the first embodiment, since good frequency spectrum characteristics can be obtained with a smaller number of control bits, it is possible to realize a circuit with good frequency spectrum characteristics on a small circuit scale.

Furthermore, in the semiconductor device 1 according to the first embodiment, it is possible to reduce the noise level in the side lobe frequency band by making the timing of switching the logic level of the selection signal EN non-uniform.

Moreover, from the above description, the first embodiment can be considered as a method of amplifying an input phase-modulated signal using multiple amplifiers and generating an output signal by adding and synthesizing each output voltage. Specifically, the method according to the first embodiment involves outputting a selection signal that sequentially switches the number of amplifiers controlled to the operating state simultaneously among multiple amplifiers based on a predetermined sequence by the amplitude control circuit, at temporally non-uniform timings and in multiple stages; using at least one first amplifier among the multiple amplifiers to change the voltage level of the output signal by a change amount smaller than the unit amplitude obtained by dividing the maximum amplitude of the output signal by the number of switching stages, which is the number of change stages of the number of amplifiers controlled to the operating state simultaneously by the amplitude control circuit; using at least one second amplifier among the multiple amplifiers to change the voltage level of the output signal by a change amount larger than the unit amplitude; and generating an output signal by controlling with the amplitude control circuit to shape the waveform of the portion with large curvature of the output signal by the output voltage of the first amplifier and the waveform of the portion with small curvature of the output signal by the output voltage of the second amplifier.

### Second Embodiment

In the second embodiment, semiconductor device 2, which is a modified example of the semiconductor device 1 according to the first embodiment, will be described. In the description of the second embodiment, the same components as those described in the first embodiment are denoted by the same reference numerals as in the first embodiment, and the description thereof will be omitted.

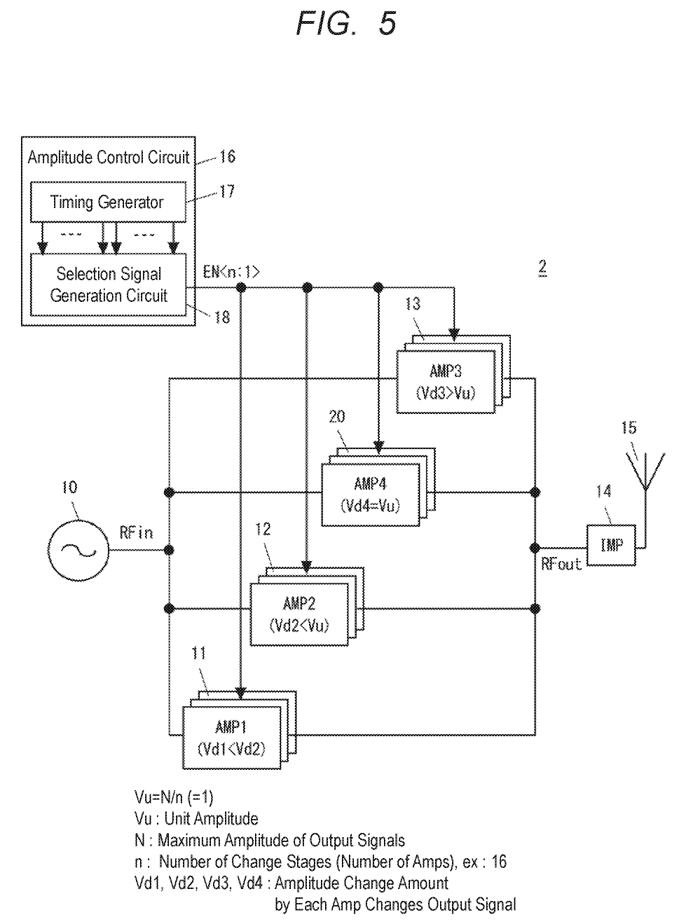

FIG. 5 shows a block diagram of the semiconductor device according to the second embodiment. As shown in FIG. 5, semiconductor device 2 according to the second embodiment is obtained by adding an amplifier unit 20 to the semiconductor device 1 according to the first embodiment. In other words, semiconductor device 2 according to the second embodiment, uses four types of amplifiers with different amplitude change amounts. Here, in the semiconductor device 2 according to the second embodiment, the amplitude changes amount of the amplifier unit 20 is set to the same value as the unit amplitude Vu. Then, the semiconductor device 2 according to the second embodiment sets the amplitude change amount Vd1 of the amplifier unit 11 to 1/3 of the unit amplitude Vu, the amplitude changes amount Vd2 of the amplifier unit 12 to 2/3 of the unit amplitude Vu, and the amplitude change amount Vd3 of the amplifier unit 13 to 4/3 of the unit amplitude Vu.

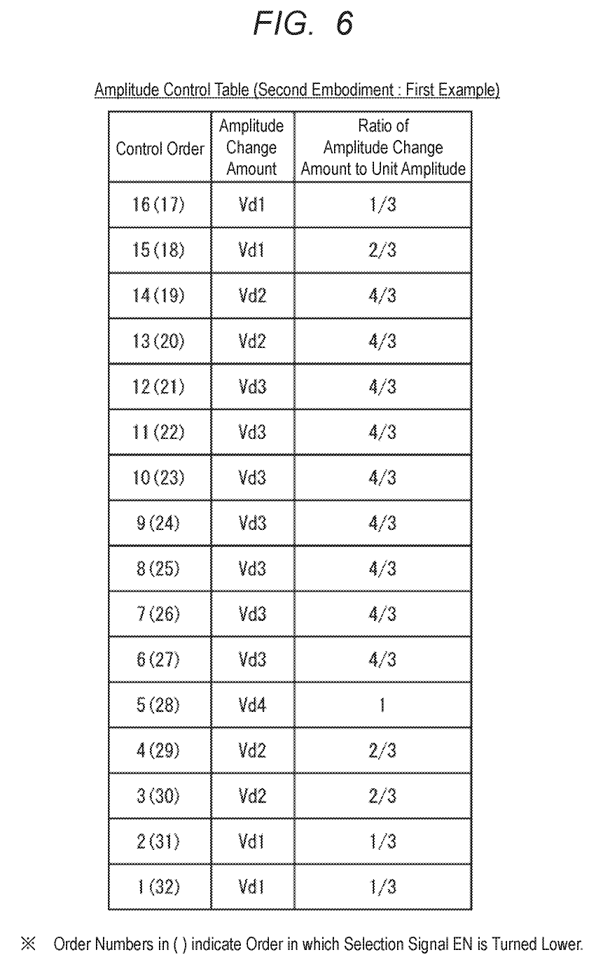

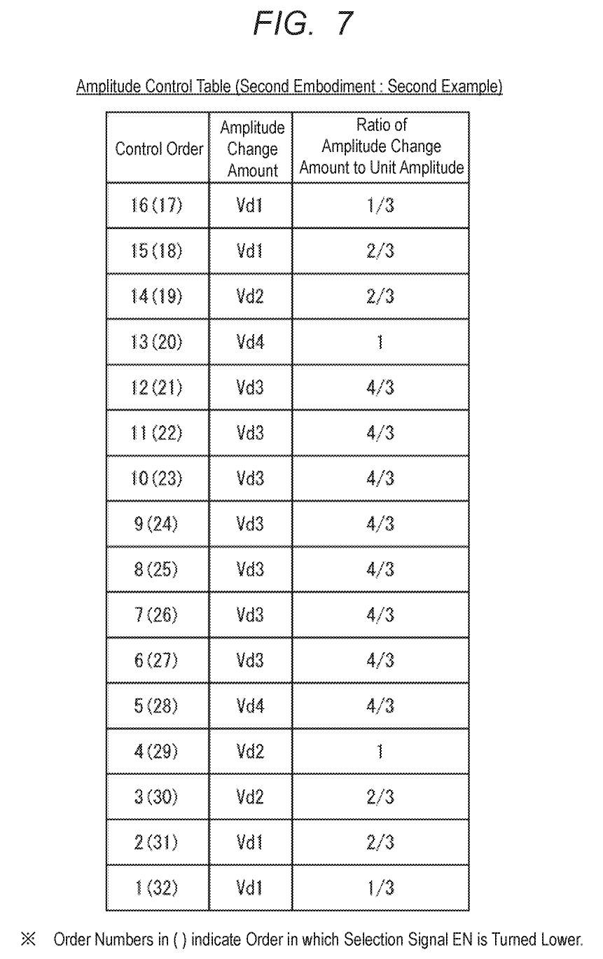

Next, FIG. 6 shows a first example of an amplitude control table applied to the semiconductor device according to the second embodiment. Also, FIG. 7 shows a second example of an amplitude control table applied to the semiconductor device according to the second embodiment.

The example shown in FIG. 6 is an example in which one third amplifier with the same amplitude change amount Vd4 as the unit amplitude Vu is set. The example shown in FIG. 7 is an example in which two third amplifiers with the same amplitude change amount Vd4 as the unit amplitude Vu are set. Then, as shown in the first and second examples, in the semiconductor device 2, the allocation of amplitude change amounts is set so that the total amount of amplitude change amounts of the 16 amplifiers is set to 16, which is the maximum amplitude N.

From the above description, the multiple amplifiers included in the semiconductor device 2 may include amplifiers with an amplitude change amount Vd4 that is the same as the unit amplitude Vu.

### Third Embodiment

In the third embodiment, specific examples of the amplifiers included in the semiconductor device 1 according to the first embodiment and the semiconductor device 2 according to the second embodiment will be described. In the explanation of the second embodiment, the same components as those described in the first embodiment are denoted by the same reference numerals as in the first embodiment, and the explanation is omitted.

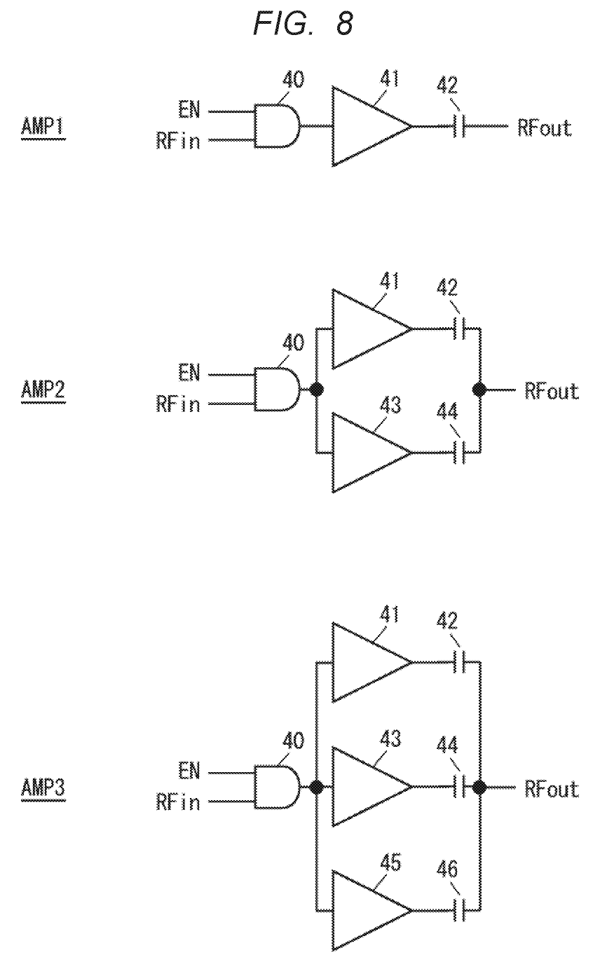

FIG. 8 shows a block diagram of the amplifier according to the third embodiment. In FIG. 8, specific circuit examples of AMP1 corresponding to amplifier unit 11, AMP2 corresponding to amplifier unit 12, and AMP3 corresponding to amplifier unit 13 are shown. In the third embodiment, the amplitude variation of multiple amplifiers included in the semiconductor device is set such that the smallest amplitude variation Vd1 is 1x, the amplitude variation Vd2 is 2x, and the amplitude variation Vd3 is 3x. By setting the amplitude variations Vd1, Vd2, and Vd3 in this manner, as shown in FIG. 8, an amplifier with multiple amplitude variations can be configured simply by changing the number of unit amplifiers connected in parallel, making design easier.

In the example shown in FIG. 8, AMP1 with an amplitude variation of 1/3x includes an AND circuit 40, a unit amplifier 41, and a coupling capacitor 42. The AND circuit 40 gates the input signal RFin based on the selection signal EN. The unit amplifier 41 amplifies the input signal RFin that has passed through the AND circuit 40 and outputs it. The coupling capacitor 42 outputs the AC component of the signal output from the unit amplifier 41 as the output signal RFout.

AMP2 with an amplitude variation of 2/3x is AMP1 with an added unit amplifier 43 and coupling capacitor 44. The unit amplifier 43 and coupling capacitor 44 are connected in parallel with the unit amplifier 41 and coupling capacitor 42. AMP3 with an amplitude variation of 1x is AMP2 with an added unit amplifier 45 and coupling capacitor 46. The unit amplifier 45 and coupling capacitor 46 are connected in parallel with unit amplifiers 41, 43 and coupling capacitors 42, 44.

Here, the method for calculating the amplitude variation of the unit amplifier is explained. When the number of amplifiers is n, the maximum amplitude of the output signal RFout is N, the number of change stages is n, h is a number smaller than n, and the number of types of change amounts set for amplifiers included in multiple amplifiers is m, the smallest change amount among the amplifiers included in multiple amplifiers (e.g., the amplitude variation of the unit amplifier) is set to a size calculated by (N/h)/m.

Specifically, the configuration of the amplifier according to the first embodiment can be calculated with N=16, h=12, m=3, and in this case, the amplitude variation of the unit amplifier is 4/9. Also, the configuration of the amplifier according to the second embodiment can be calculated with N=16, h=12, m=4, and in this case, the amplitude variation of the unit amplifier is 1/3.

By setting the amplitude variation of the unit amplifier in this way and changing the number of unit amplifiers connected in parallel within one amplifier, the design of multiple amplifiers with different amplitude variations becomes easier.

### Fourth Embodiment

In the fourth embodiment, semiconductor device 3, which is a modified example of the semiconductor device 1 according to the first embodiment, is described. In the explanation of the fourth embodiment, the same components as those described in the first embodiment are denoted by the same reference numerals as in the first embodiment, and the explanation is omitted.

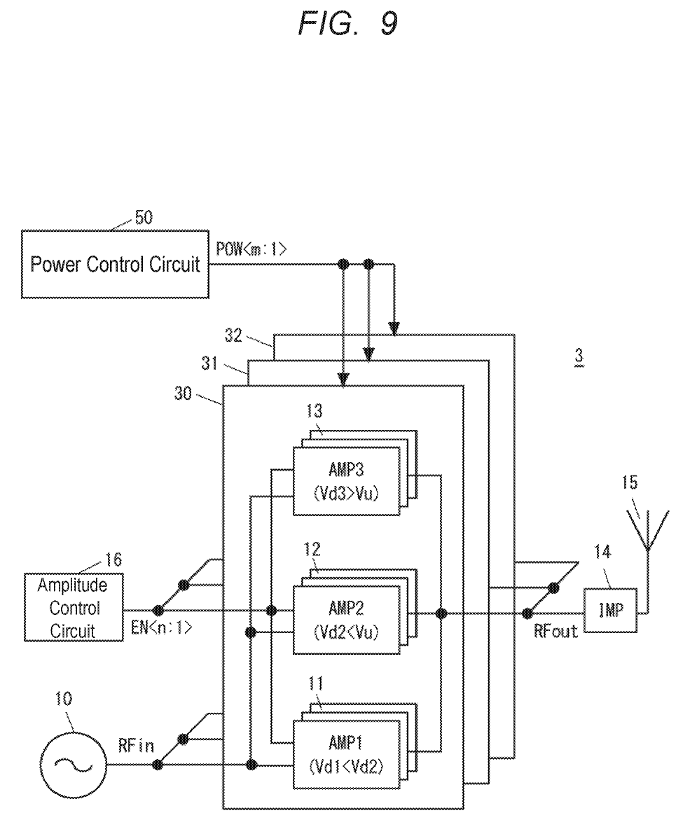

FIG. 9 shows a block diagram of the semiconductor device 3 according to the fourth embodiment. As shown in FIG. 9, the semiconductor device 3 according to the fourth embodiment includes power units 30, 31, and 32, each containing a set of amplifier units 11 to 13 of the first embodiment. In other words, the semiconductor device 3 according to the fourth embodiment has multiple power units, each with the same number of amplifiers as the number of change stages, as one control unit.

Additionally, the semiconductor device 3 according to the fourth embodiment, has a power control circuit 50 added to the semiconductor device 1. The power control circuit 50 outputs a power control signal POW that switches the number of power units to be operated according to a power designation value. The power designation value is a control value provided from other processing blocks not shown or from outside the semiconductor device. The semiconductor device 3 according to the fourth embodiment changes the number of power units to be operated in parallel simultaneously by the power control signal POW to increase or decrease the output power of the output signal RFout.

From the above explanation, the semiconductor device according to the fourth embodiment can increase or decrease the output power of the output signal RFout.

It should be noted that the present invention is not limited to the above embodiments and can be appropriately modified within a range not departing from the spirit of the invention. In the above embodiment, the number of first amplifiers that change the voltage level of the output signal with a smaller change amount than the unit amplitude is greater than the number of second amplifiers that change the voltage level of the output signal with a larger change amount than the unit amplitude, but the number of second amplifiers can also be increased compared to the number of first amplifiers. In other words, the second amplifier can be configured to include a first large amplitude amplifier larger than the unit amplitude and a second large amplitude amplifier that changes the amplitude of the output signal with a larger change amount than the first large amplitude amplifier.

What is claimed is:

1. A semiconductor device comprising:
a plurality of amplifiers configured to amplify an input phase-modulated signal and to generate an output signal by adding and combining respective output voltages thereof; and
an amplitude control circuit configured to output a selection signal that sequentially switches, in multiple stages and at temporally non-uniform intervals, a number of amplifiers among the plurality of amplifiers that are simultaneously controlled to an operating state, based on a predetermined sequence,
wherein a number of stages of change in the number of amplifiers simultaneously controlled to the operating state by the amplitude control circuit is defined as a switching stage number, and
wherein the plurality of amplifiers include at least one first amplifier configured to change a voltage level of the output signal by an amount of change smaller than a unit amplitude obtained by dividing a maximum amplitude of the output signal by the switching stage number, and at least one second amplifier configured to change the voltage level of the output signal by an amount of change larger than the unit amplitude.

2. The semiconductor device according to claim 1,
wherein the first amplifier includes a first small-amplitude amplifier configured to change the amplitude of the output signal by an amount smaller than the unit amplitude, and
a second small-amplitude amplifier configured to change the amplitude of the output signal by an amount larger than that of the first small-amplitude amplifier and smaller than the unit amplitude.

3. The semiconductor device according to claim 1,
wherein the second amplifier includes a first large-amplitude amplifier configured to change the amplitude of the output signal by an amount larger than the unit amplitude, and
a second large-amplitude amplifier configured to change the amplitude of the output signal by an amount larger than that of the first large-amplitude amplifier.

4. The semiconductor device according to claim 1, wherein the plurality of amplifiers include a third amplifier configured to change the amplitude of the output signal by an amount equal to the unit amplitude.

5. The semiconductor device according to claim 1, wherein a number of the plurality of amplifiers is equal to the switching stage number.

6. The semiconductor device according to claim 1, further comprising:
a plurality of power units, each power unit including, as one control unit, the plurality of amplifiers in a number equal to the switching stage number; and
a power control circuit configured to switch a number of the power units to be operated in accordance with a power designation value.

7. The semiconductor device according to claim 1,
wherein a second change amount by which the second amplifier changes a voltage level of the output signal is an integer multiple of a first change amount by which the first amplifier changes the voltage level of the output signal.

8. The semiconductor device according to claim 1,
wherein, when a number of the plurality of amplifiers is n,
a maximum amplitude of the output signal is N,
the switching stage number is n,
h is a number smaller than n, and
a number of types of change amounts set for amplifiers included in the plurality of amplifiers is m,
a smallest change amount among amplifiers included in the plurality of amplifiers is set to a magnitude calculated by (N/h)/m.

9. The semiconductor device according to claim 8,
wherein (N/h)/m is defined as a unit change amount,
a unit amplifier configured to output the unit change amount is provided, and
the first amplifier and the second amplifier each include a configuration in which a number of the unit amplifiers corresponding to a magnitude of a set change amount are connected in parallel.

10. A method of generating an output signal by amplifying an input phase-modulated signal using a plurality of amplifiers and adding and combining respective output voltages thereof, the method comprising:
outputting, by an amplitude control circuit, a selection signal that sequentially switches, in multiple stages and at temporally non-uniform intervals, a number of amplifiers among the plurality of amplifiers that are simultaneously controlled to an operating state, based on a predetermined sequence;
defining a number of stages of change in the number of amplifiers simultaneously controlled to the operating state by the amplitude control circuit as a switching stage number;
changing, by at least one first amplifier among the plurality of amplifiers, a voltage level of the output signal by an amount of change smaller than a unit amplitude obtained by dividing a maximum amplitude of the output signal by the switching stage number;
changing, by at least one second amplifier among the plurality of amplifiers, the voltage level of the output signal by an amount of change larger than the unit amplitude; and
generating the output signal by shaping a portion of a waveform of the output signal having large curvature using an output voltage of the first amplifier and shaping a portion of the waveform of the output signal having small curvature using an output voltage of the second amplifier under control of the amplitude control circuit.
